(19) United States
(12) Patent Application Publication
(10) Pub. No.: US 2026/0096044 A1
(43) Pub. Date: Apr. 2, 2026

(54) SOLAR POWER PROCESSING MODULES WITH SELF-GUIDING UNIVERSAL CONNECTORS

(71) Applicant: Nextracker LLC, Fremont, CA (US)

(72) Inventors: Niloofar Torabi, Redwood City, CA (US); Jason Sean Henry, Redwood City, CA (US); Alexander W. AU, Oakland, CA (US)

(21) Appl. No.: 19/339,680

(22) Filed: Sep. 25, 2025

Related U.S. Application Data
(60) Provisional application No. 63/701,810, filed on Oct. 1, 2024.

(51) Int. Cl. H05K 7/14; H02M 3/00; H02M 7/00

(52) U.S. Cl. CPC H05K 7/14; H02M 3/003; H02M 7/003

(57) ABSTRACT

A modular power processing system for renewable energy applications includes rack-supported power processing modules with power conversion circuitry for AC/DC and/or DC/DC conversion. Each module can include top and bottom connectors that self-align and engage to establish electrical communication, with optional locking mechanisms to prevent disconnection. Connector covers can be included to protect exposed connectors. The system can include an endpoint module for external electrical connections and supports both active and passive cooling elements. Electrical communication between modules can transmit power and data. Modules are designed for tool-less addition or removal, enabling rapid installation and expansion. The system can be used for outdoor use and is scalable, whereby multiple power processing system are connected to each other.

### RELATED APPLICATION

This application claims priority to U.S. Provisional Patent Application No. 63/701,810, filed on Oct. 1, 2024, the entire contents of which are hereby incorporated by reference.

### TECHNICAL FIELD

This disclosure generally relates to connections for electrical power converters and inverters.

### BACKGROUND

Integrating multiple renewable energy sources together, such as different arrays of photovoltaic (PV)/solar panels, and further integrating energy storage devices, such as batteries, can be complex. Current solutions often involve using separate power converters, such as DC/DC power converters, and inverters for each energy source and/or for each energy storage device. Further, if more renewable energy capacity and/or energy storage is added after a system has already been built, additional power converters and inverters are needed to interconnect the existing renewable energy sources and energy storage devices with the new renewable energy sources and energy storage devices. It can be difficult to incorporate any additional power converters and inverters necessary into an existing system. While some power converters and inverters can be made to fit into a rack mounted system, connecting such converters/inverters may be time consuming and require special tools/knowledge.

### SUMMARY

In general, this disclosure describes power processing modules that can be easily connected together and mounted in a rack system. In particular, embodiments disclosed herein enable power processing modules including electrical power converters (e.g., DC/DC converters) and/or inverters (e.g., DC/AC inverters) to be easily connected together in a rack mounting system to expand power processing capacity. In addition, embodiments disclosed herein provide various methods for both active and passive cooling of power processing modules.

In one example of the present disclosure, a modular power processing system includes a first power processing module supported by a rack structure. The first power processing module includes power conversion circuitry configured to convert power between AC and DC, or between different DC voltages. The first module includes a top connector. A second power processing module is also supported by the rack structure. The second power processing module includes power conversion circuitry specific to the second module and a bottom connector. The top connector of the first module is configured to align and engage with the bottom connector of the second module. This engagement establishes electrical communication between the first and second modules.

In one example of the present disclosure, a method of installing modules into a modular power processing rack system includes installing an endpoint module into a rack structure. The method further includes installing a first power processing module by moving the first power processing module horizontally relative to the endpoint module. This movement causes alignment and engagement of a bottom connector of the first power processing module with a top connector of the endpoint module, and establishes electrical communication. A second power processing module is then installed by moving the second power processing module horizontally relative to the first power processing module. This movement aligns and engages a bottom connector of the second power processing module with a top connector of the first power processing module, and establishes electrical communication between the modules.

The details of one or more examples are set forth in the accompanying drawings and the description below. Other features, objects, and advantages will be apparent from the description and drawings, and from the enumerated embodiments.

### BRIEF DESCRIPTION OF DRAWINGS

The following drawings are illustrative of particular examples of the present invention and therefore do not limit the scope of the invention. The drawings are intended for use in conjunction with the explanations in the following detailed description wherein like reference characters denote like elements. Examples of the present invention will hereinafter be described in conjunction with the appended drawings.

FIG. 1 is a schematic side view of an example rack system including connected power processing modules and an endpoint module according to an aspect of the present disclosure.

FIG. 2 is a schematic front view of the example rack system of FIG. 1 according to an aspect of the present disclosure.

FIG. 3 is a schematic side view of an example power processing module and endpoint module with example connectors and a connector cover according to an aspect of the present disclosure.

FIG. 4 is a perspective view of multiple power processing modules, an endpoint module, and a connector cover according to an aspect of the present disclosure.

FIG. 5 is a schematic side view of an example rack system including power processing modules and an endpoint module connected with jumpers according to an aspect of the present disclosure.

FIG. 6 is a schematic front view of multiple example rack systems, including power processing modules, connected together and to an external electrical element according to an aspect of the present disclosure.

FIG. 7 is a flow diagram of an example method of installing modules into a rack system according to an aspect of the present disclosure.

FIG. 8A is a schematic top view of an example power processing module with passive cooling according to an aspect of the present disclosure.

FIG. 8B is a schematic top view of an example power processing module with active cooling according to an aspect of the present disclosure.

FIG. 8C is a schematic top view of an alternate example power processing module with passive cooling according to an aspect of the present disclosure.

FIG. 9 is a schematic side view of an example rack system including power processing modules, an endpoint module, and a cooling system according to an aspect of the present disclosure.

### DETAILED DESCRIPTION

The following detailed description is exemplary in nature and is not intended to limit the scope, applicability, or configuration of the invention in any way. Rather, the following description provides some practical illustrations for implementing examples of the present invention. Those skilled in the art will recognize that many of the noted examples have a variety of suitable alternatives.

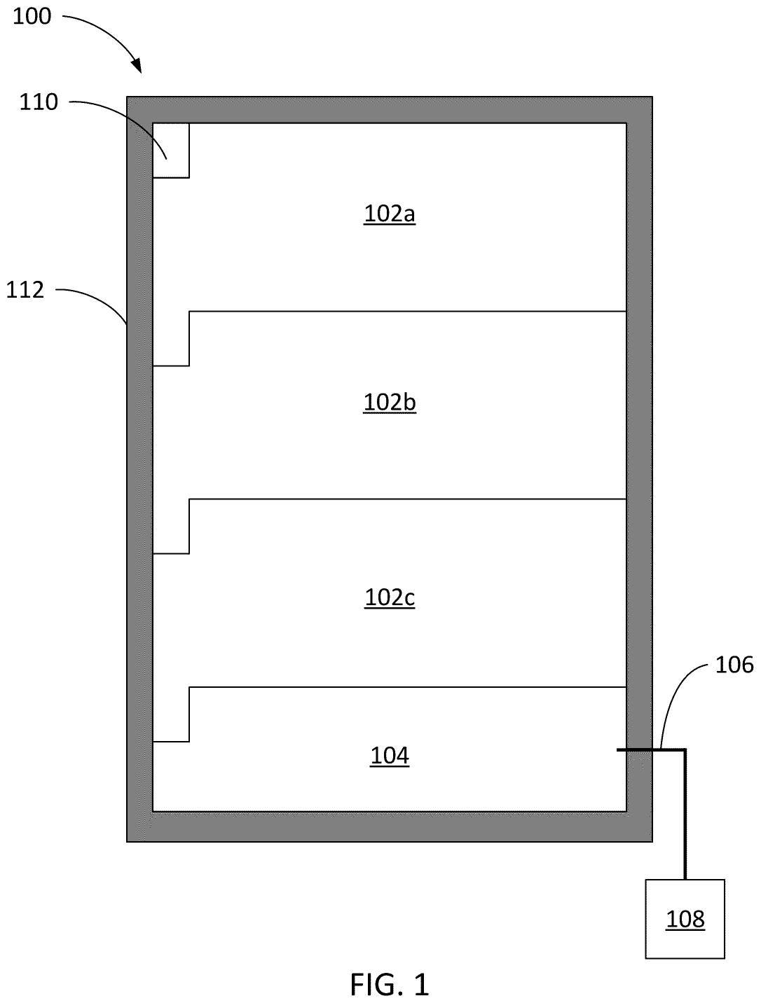

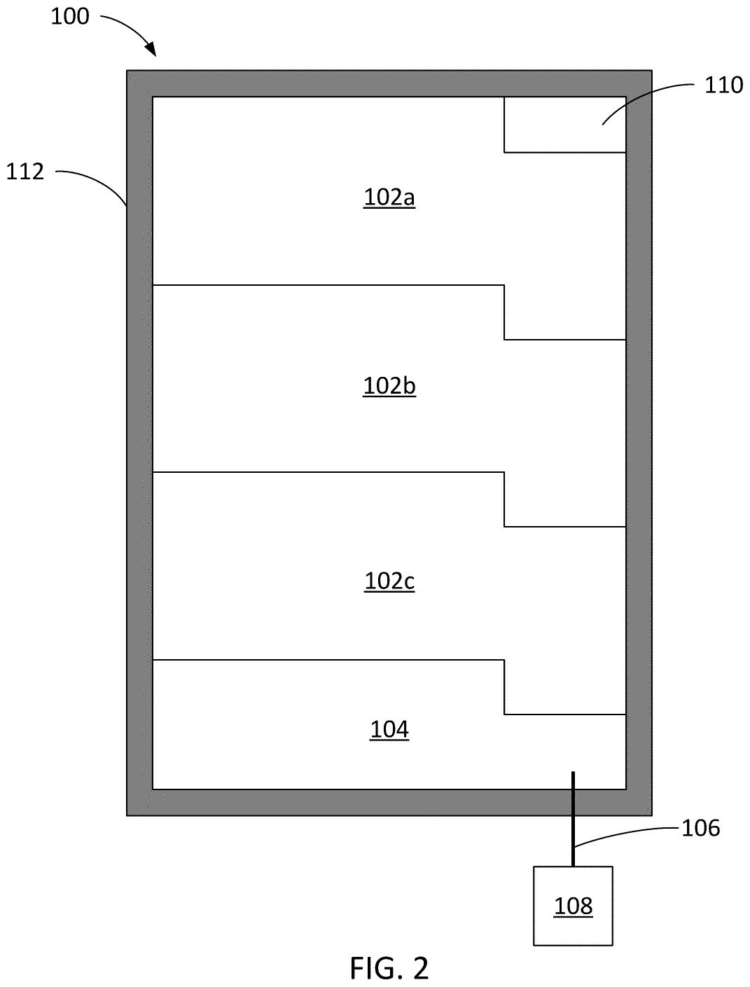

Referring to both FIG. 1 and FIG. 2, FIG. 1 is a schematic side view of an example rack system 100 including power processing modules 102a-c and an electrical bus endpoint module 104 (also referred to as “endpoint module”) while FIG. 2 is a schematic front view of the example rack system 100 of FIG. 1. The power processing modules 102a-c are stacked within the rack system 100 with each power processing module 102a-c connected to a top and/or bottom power processing module. For example, the “middle” power processing module 102b is electrically connected to both a topmost power processing module 102a and a bottommost power processing module 102c. Further, the bottommost power processing module 102c is electrically connected to the endpoint module 104. The electrical connection between the bottommost power processing module 102c and the endpoint module 104 enables the other power processing modules 102a,b to also electrically connect to the endpoint module 104 (e.g., through the bottommost power processing module 102c). This electrical connection enables a common bus that is shared amongst the power processing modules 102a-c and the endpoint module 104. The endpoint module 104 can also connect to one or more external electrical elements 108 via an external electrical connection 106, thereby enabling the power processing modules 102a-c to also connect to the one or more external electrical elements 108 (e.g., via a shared bus). The external electrical connection 106 can comprise one or more connections to the one or more external electrical elements 108.

In some examples, the one or more external electrical elements 108 comprise electrical device(s) that connect the power processing modules 102a-c and the endpoint module 104 to an electrical grid. For instance, the one or more external electrical elements 108 can comprise electrical switchgear, disconnects, transformers, fuses, and the like. In some examples, the one or more external electrical elements 108 comprises a connection to another rack system 100. In some examples, the one or more external electrical elements 108 comprise a plurality of solar panels, solar trackers, and/or batteries.

The power processing modules 102a-c can comprise DC/DC converters (e.g., buck-boost converters), AC/DC converters (e.g., inverters), and/or cooling components, as well as other circuitry and components necessary to operate the DC/DC converters, AC/DC converters, and/or cooling components. In some examples, the power processing modules 102a-c comprise substantially the same components. For instance, the power processing modules 102a-c can include DC/DC converters that receive a first DC voltage (e.g., from one or more solar trackers) as an input and output a second DC voltage. In some examples, an input DC voltage is received via the external electrical connection 106. Similarly, in some examples, an output DC voltage is output via the external electrical connection. Additionally or alternatively, in some examples, a DC voltage is output from a power processing module configured as a DC/DC converter to another power processing module which can be configured as an AC/DC converter. In some such examples, the AC/DC converter can convert the DC input voltage into an AC voltage that can be output to one or more external electrical elements 108 via the external electrical connection 106.

The endpoint module 104 can comprise similar components as the power processing modules 102a-c. For example, the endpoint module 104 can include active cooling components (e.g., fans). In some examples, the endpoint module 104 includes communication and/or control circuitry to control the power processing modules 102a-c. In FIG. 1 and FIG. 2, the endpoint module 104 includes an external electrical connection 106 that can connect to the one or more external electrical elements 108. For example, the endpoint module 104 can connect to an electrical utility's infrastructure (e.g., transformer, switchgear, electrical disconnect) via the external electrical connection 106. In some examples, the external electrical connection 106 includes a connection that transfers data. For instance, the endpoint module 104 can receive data that includes control commands which the endpoint module 104 can use to control aspects of the power processing modules 102a-c.

The rack system 100 of FIG. 1 and FIG. 2 further includes a connector cover 110 that is connected to the topmost power processing module 102a. The rack system 100 also includes a rack structure 112 in which the power processing modules 102a-c, the endpoint module 104, and the connector cover 110 are all enclosed. The rack structure 112 can include mechanisms for mounting the power processing modules 102a-c and the endpoint module 104 within the rack structure 112. In some examples, the mechanisms for mounting can include sliding mechanisms that slide into and out of the rack structure 112. The rack structure 112 can also include locking mechanisms to prevent modules from moving, such as being slide out of the rack structure. In some examples, the rack structure 112 is a standardized size, such as a size specified by the International Electrotechnical Commission (IEC).

In the illustrated example, three power processing modules 102a-c and a single endpoint module 104 are included in the rack system 100. However, any number of power processing modules and/or endpoint module can be used. In some examples, one endpoint module is used with a variable number of power processing modules.

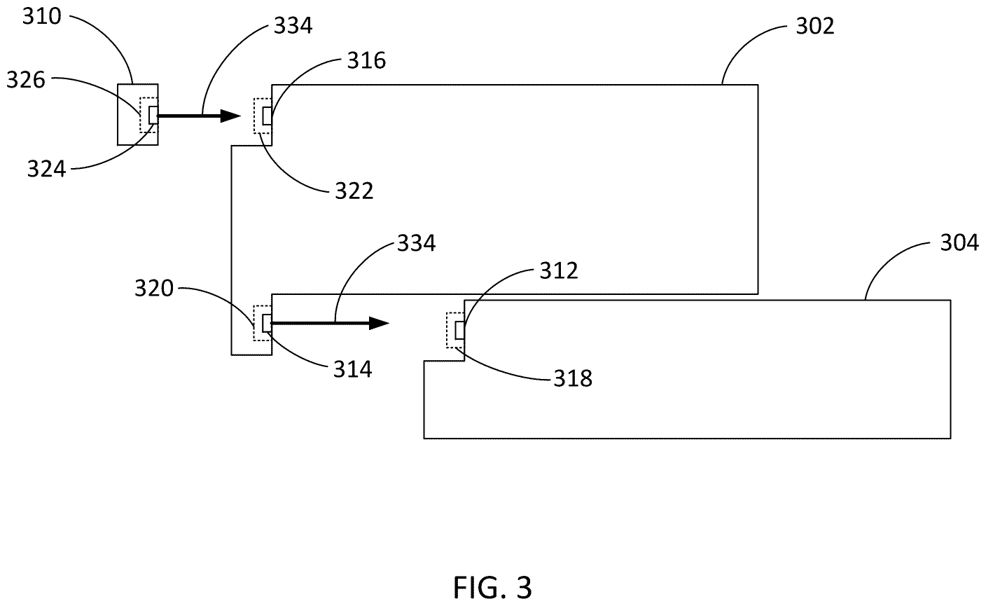

FIG. 3 is a schematic side view of an example power processing module 302 and endpoint module 304 with example connectors for electrical connections. The endpoint module 304 has a connector 312 to which a bottom connector 314 of the power processing module 302 connects. With the connection, the power processing module 302 can electrically connect to the endpoint module 304 such that power (e.g., voltage and current) can transfer between them. In some examples, the electrical connection between the endpoint module 304 and the power processing module 302 can enable the endpoint module 304 and the power processing module 302 to electrically communicate (e.g., send/receive data). In addition to the bottom connector 314, the power processing module 302 has a top connector 316. In the example of FIG. 3, the top connector 316 is connected to a connector cover 310. However, in some examples, the top connector 316 of the power processing module 302 can be connected to a bottom connector of another power processing module. For example, as illustrated in FIG. 1 and FIG. 2, the bottommost power processing module 102c is connected to a middle power processing module 102b, with the middle power processing module 102b also connected to a topmost power processing module 102a.

In the illustrated example of FIG. 3, the connections comprise “plug and socket” connections whereby one connector projects outward and can be inserted into a receiving connector that has a corresponding receptacle. For example, the connector 312 extends outward from the endpoint module 304, thereby comprising the “plug”, while the receiving connector 314 of the power processing module 302 has a receptacle that is inset into the power processing module 302, thereby comprising the “socket”. To make the connection between the top connector 312 of the endpoint module 304 and the bottom connector 314 of the power processing module 302, the power processing module 302 is moved toward the endpoint module 304 as illustrated by arrow 334, which shows the direction of movement. When the two connectors 312, 314 are brought together, electrical contacts in the connector 312 that project outward make contact with electrical contacts contained within the connector 314, thereby establishing an electrical connection between the power processing module 302 and the endpoint module 304. A similar connection can be made between the top connector 316 of the power processing module 302 and a bottom connector of another power processing module (e.g., as illustrated in FIG. 1 and FIG. 2). In such a configuration, the top connector of the first power processing module comprises the “plug” while the bottom connector of the second power processing again comprises the “socket.” In some examples, though, the “plug” and “socket” of each connection can be reversed. For instance, the connector 312 can comprise a “socket” with the corresponding connector 314 comprising a “plug”. Similarly, the top connector 316 can comprise a “socket” and the connector cover 310 can comprise a corresponding “plug”. In some examples, the top connector of a power processing module comprises the corresponding connector to the bottom connector of the power processing module such that a second power processing module can be connected. For example, if the top connector (e.g., 316) comprises a “plug” connector, the bottom connector (e.g., 314) comprises the corresponding “socket” connector. Similarly, if the top connector comprises a “socket” connector, the bottom connector comprises the corresponding “plug” connector. While the connectors illustrated in FIG. 3 are of the “plug and socket” type, other types of connectors are contemplated and this disclosure is not limited to the example types of connectors provided herein.

In some examples, electrical contacts of the connectors (e.g., 312, 314) do not engage with each other until the corresponding modules are fully connected. For instance, the electrical contacts of the power processing module 302 may only contact the corresponding electrical contacts of the endpoint module 304 when the power processing module 302 is fully engaged with the endpoint module 304. Such an arrangement of the electrical contacts can prevent accidental connection/disconnection.

Further, as illustrated in the example of FIG. 3, each of the connectors can include a protective/guiding element. The protective/guiding element can help prevent damage to the corresponding connector. For example, the connector 312 of the endpoint module 304 projects outward and can be vulnerable to physical damage. Accordingly, the protective/guiding element 318 can surround the connector 312 and help prevent such physical damage. The protective/guiding element can also act as a guide, whereby when a module (e.g., power processing module) is connected to another module (e.g., endpoint module and/or power processing module), the protective/guiding element can guide a projecting connector to properly engage with a corresponding receptacle connector. For example, the “plug” connector 312 includes the protective/guiding element 318 which when inserted into the “socket” connector 314 engages the protective/guiding element 320. The engagement between the two protective/guiding elements 318, 320 can align the electrical contacts of the connectors 312, 314 such that they are in proper electrical communication with each other (e.g., not partially connected/disconnected).

In some examples, a locking mechanism is included with the connectors (e.g., 312, 314) and can prevent accidental disconnection of a connector from another connector. The locking mechanism also includes a release mechanism that enables connectors to be disconnected from each other. In the example of FIG. 3, a locking mechanism can prevent the connector 314 of the power processing module 302 from being disconnected from the connector 312 of the endpoint module 304 without activation of a release mechanism. In some examples, the locking mechanism only engages when the corresponding connectors are fully engaged with each other (e.g., electrical contacts of each connector in full contact). In some examples, the locking mechanism is separate from the connectors. However, in some examples, the locking mechanism is integrated into one or both of the connectors and the corresponding protective/guiding elements of the connectors. For instance, the locking mechanism can be partially included in the protective/guiding element 320 of the power processing module 302 and the protective/guiding element 318 of the endpoint module 304. Similarly, a portion of a locking mechanism for the top connector 316 of the power processing module 302 can be in the protective/guiding element 322.

To further protect the connectors, and more specifically to protect a connector which is unconnected (e.g., exposed), a connector cover 310 can be used. For example, the connector cover 310 can help protect the top connector 316 of the power processing module 302 from damage and accidental contact with the top connector 316. The connector cover 310 can secure to the top connector 316 via various means including using fasteners, a friction fit, plug and socket connectors, and the like. In some examples, the connector cover 310 also includes a portion of a locking mechanism to secure to the connector it is covering. For example, the connector cover 310 can include a protective/guiding element 326 that has a part of a locking mechanism that engages and locks with the corresponding protective/guiding element 322 of the power processing module 302. The connector cover 310 can prevent contact with live electrical contacts and can physically protect connectors to which it is connected. In some examples, the connector cover 310 can be used to protect connectors of modules during times of transit (e.g., shipping).

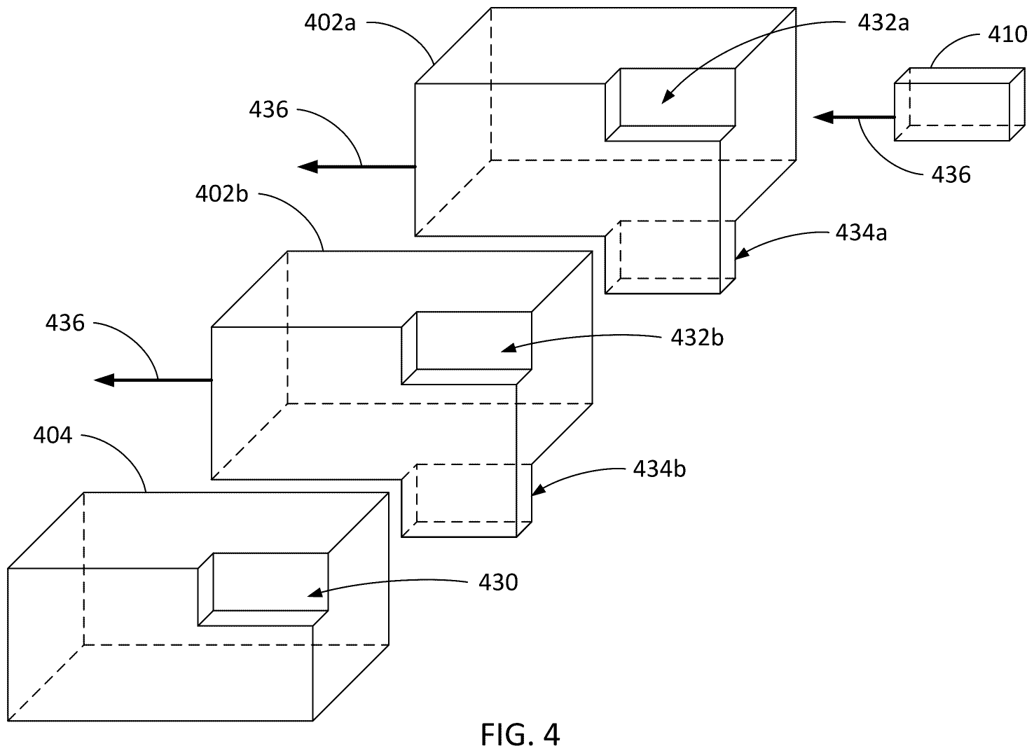

FIG. 4 is a perspective view of multiple power processing modules, 402a,b, an endpoint module 404, and a connector cover 410 according to an aspect of the present disclosure. The endpoint module 404 comprises a bottom portion to which a lower power processing module 402b electrically connects. Similarly, an upper power processing module 402a electrically connects to the lower power processing module 402b. Further, the connector cover 410 connects to the upper power processing module 402a.

In the example of FIG. 4, the endpoint module 404 defines a connection slot 430 where one or more connectors (e.g., the connectors shown and described in FIG. 3) and one or more protective/guiding elements (e.g., protective/guiding element 318) can be located. The connection slot 430 is sized and shaped to receive a corresponding connection extension 434b of the lower power processing module 402b. As with the connection slot 430, the connection extension 434b of the lower power processing module 402b can include one or more connectors and one or more protective/guiding elements such as those shown and described in FIG. 3. The connection extension 434b, though, can include the complementing connector(s) to the connector(s) of the connection slot 430. For example, the connection extension 434b can include a “plug” type connector while the connection slot 430 includes a “socket” type connector. Accordingly, to connect the lower power processing module 402b to the endpoint module 404, the lower power processing module 402b is positioned such that the one or more connectors of the connection extension 434b engage with the corresponding one or more connectors of the connection slot 430. In some examples, the lower power processing module 402b is moved laterally (e.g., slid) relative to the endpoint module 404 to make such a connection. The arrow 436 illustrates the direction of movement of the lower power processing module 402b relative to the endpoint module 404. In some examples, the lower power processing module 402b partially contacts the endpoint module 404 at points other than the connectors (e.g., partially rests on).

Continuing with the example of FIG. 4, the lower power processing module 402b also defines a connection slot 432b that is sized and shaped to receive a corresponding connection extension 434a of another (e.g., upper) power processing module 402a. As with the connection slot 430 of the endpoint module 404, the connection slot 432b of the lower power processing module 402b can include one or more connectors and one or more protective/guiding elements such as those shown and described in FIG. 3. Further, as with the connection extension 434b of the lower power processing module 402b, the connection extension 434a defined by the upper power processing module 402a can include one or more corresponding connectors and one or more protective/guiding elements. The connector(s) and the protective/guiding element(s) of the connection extension 434a are configured to engage with the connector(s) and protective/guiding element(s) of the connection slot 432b. Though this connection, the upper power processing module 402a can be electrically connected to the lower power processing module 402b.

In some examples, the connection slots 432a,b of the power processing modules 402a,b are substantially similar to each other and in some examples, are also substantially similar to the connection slot 430 of the endpoint module 404. In some examples, the connection extensions 434a,b of the power processing modules 402a,b are substantially similar to each other. Accordingly, the connections between the elements of FIG. 4 can be uniform such that any power processing module can be connected to any other power processing module and any power processing module can be connected to an endpoint module.

Continuing with the example of FIG. 4, the endpoint module 404, the power processing modules 402a,b, and the connector cover 410 can be connected in a specific order. In FIG. 4, for example, the endpoint module 404 can be connected in a rack system (e.g., 100) first. Next, the lower power processing module 402b can be connected to the endpoint module 404. Further, the upper power processing module 402a can be connected to the lower power processing module 402b. In FIG. 4, the connector cover 410 can be connected to the upper power processing module 402a last. However, the connector cover 410 can be connected to the upper power processing module 402a at any time including being pre-attached (e.g., before any other connections are made).

In some examples, further power processing modules can be connected in succession above the upper power processing module 402a. Such configurations can provide easy expandability of the number of power processing modules. While the order of connections in FIG. 4 is generally from bottom to top, in some examples, the connections can be from top to bottom. To enable top to bottom connections, in some examples, the endpoint module 404, the power processing modules 402a,b, and the connector cover 410 are flipped vertically (e.g., mirrored across a horizontal plane). In some such examples, the connection slots and the corresponding connection extensions are also flipped vertically such that the connection slots are located on a lower part of the endpoint module 404 and/or a lower part of the power processing modules 402a,b.

In the example of FIG. 4, the sizes and shapes of the connection slots and the corresponding connection extensions can limit the order in which connections are made. For instance, in FIG. 4, the upper power processing module 402a cannot be connected in the rack system before the lower power processing module 402b is connected to the endpoint module 404. However, the sizes and shapes of the connection slots and the corresponding connection extensions can vary and, in some examples, can enable different orders of connections. Further, other connection mechanisms can be used that enable connections in a different order.

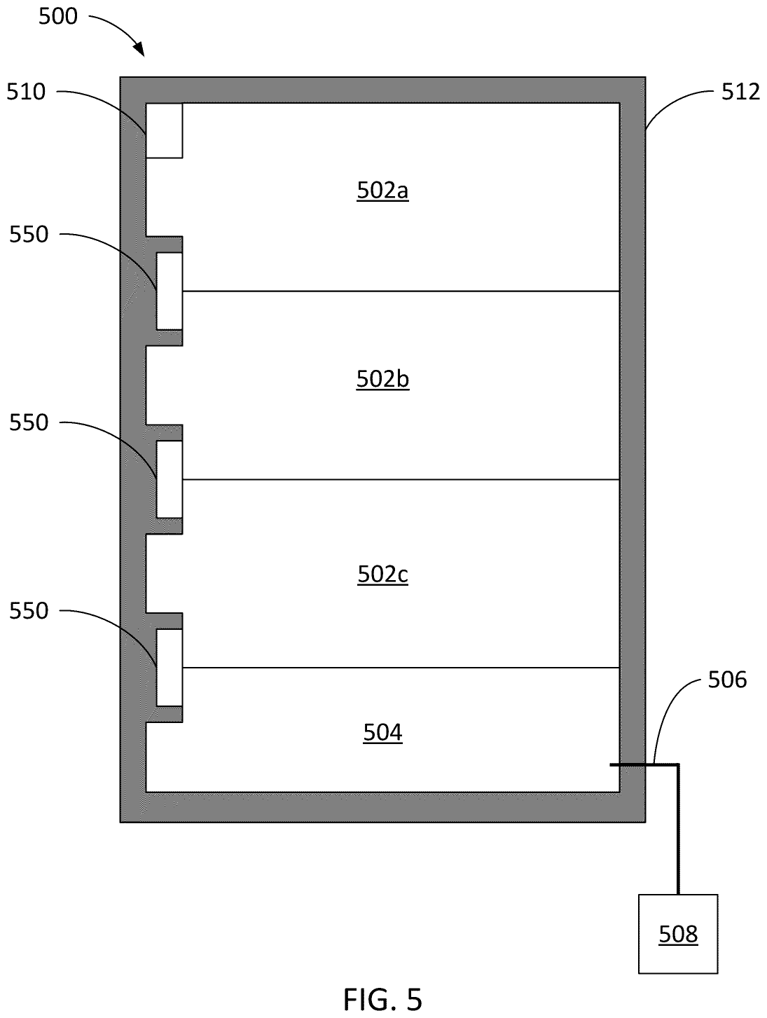

FIG. 5 is a schematic side view of an example rack system 500 including power processing modules 502a-c and an endpoint module 504 connected with jumpers 550 according to an aspect of the present disclosure. The example rack system 500 is similar to the rack system of FIGS. 1 and 2, however, the electrical connections between the power processing modules 502a-c and the endpoint module 504 are not integrated into the modules themselves. Instead, the jumpers 550 electrically connect the power processing modules 502a-c and the endpoint module 504. The jumpers 550 can comprise many forms but are substantially uniform and include at least two separate connectors with electrical contacts to connect one module with another module. For example, the bottommost jumper 550 electrically connects the endpoint module 504 with the bottommost power processing module 502c. The power processing modules 502a-c can include electrical terminals/connections to which the jumpers 550 connect. For instance, the jumpers 550 can be connected to the modules via a variety of types of connections, such as the plug and socket type connections shown and described in FIG. 3. In some examples, though, connecting the jumpers 550 to modules may include wiring separate from a mechanical/electrical connection.

The rack system includes a connection cover 510 for the unconnected portion of the topmost power processing module 502a. However, in some examples, because jumpers 550 are used to electrically connect the modules, a separate connection cover 510 is not needed. For instance, the modules may have electrical connections that have integrated covers to protect corresponding electrical contacts of the modules.

In comparison to the example of FIG. 1 and FIG. 2, the power processing modules 502a-c of FIG. 5 do not have connection extensions (e.g., 434a,b) and corresponding connection slots. Because the power processing modules 502a-c do not include connection extensions and corresponding connection slots, the order in which modules are connected and disconnected is not limited. For example, the topmost power processing module 502a can be installed into the rack structure 512 first and can also be connected to the middle power processing module 502b before the bottommost power processing module 502c is installed and/or connected. This can be advantageous as if a power processing module that is below other power processing modules fails, only a jumper and the failed power processing module need to be removed, rather than multiple power processing modules.

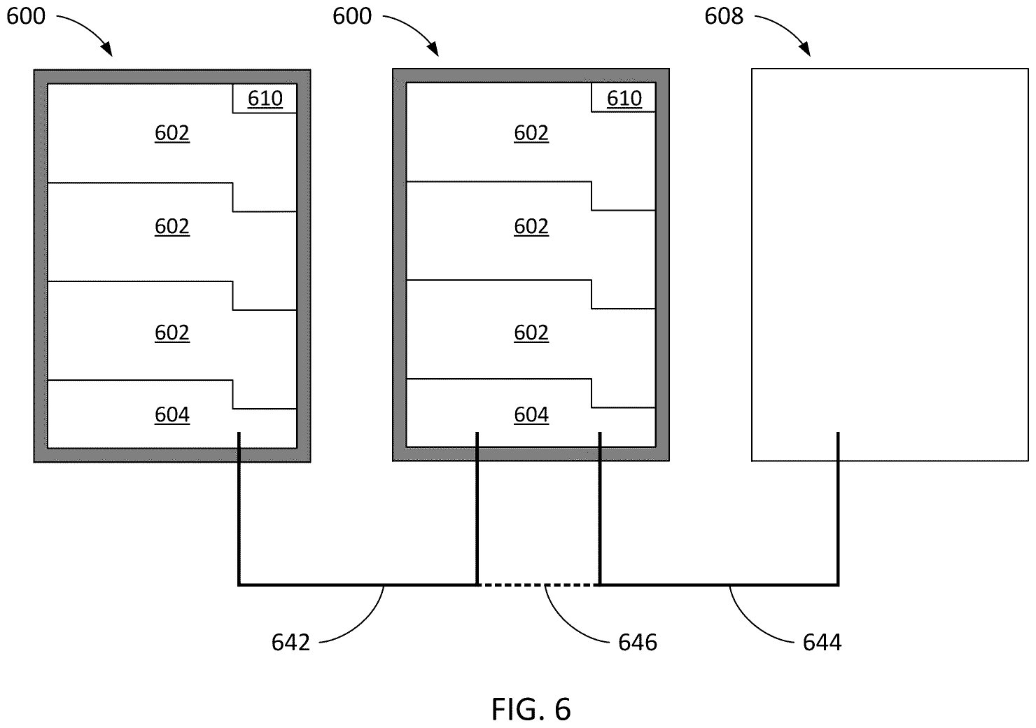

FIG. 6 is a schematic front view of multiple example rack systems 600, including power processing modules 602, connected together and to an external electrical element 608 according to an aspect of the present disclosure. Each of the rack systems 600 include power processing modules 602 and an endpoint module 604 with the endpoint modules 604 electrically connected together via the first connection 642. The rack systems 600 can be connected together in parallel, such that a voltage remains the same, or alternatively can be connected together in series, such that a current remains the same. It can be advantageous to connect the rack systems 600 together to increase (e.g., double) an energy capacity handled by the power processing modules 602. As will be appreciated, any number of rack systems 600 can be connected together, which can provide modularity and an ability to easily increase power capacity as needed. For example, each of the power processing modules 602 can be configured as DC/DC power converters for a number of solar trackers. Accordingly, if more solar trackers are added and more DC/DC power converters are needed, another rack system containing one or more power processing modules 602 can be connected to an existing rack system (or systems) to increase the capacity of the overall system.

In the example of FIG. 6, the rack systems 600 can also be connected to an external electrical element 608. The external electrical element 608 can include any number of electrical elements, such as those described relative to the external electrical element 108 of FIG. 1 and FIG. 2. For instance, in some examples, the external electrical element 608 comprises an AC/DC transformer that can receive a DC voltage from the rack systems 600 and output an AC voltage (e.g., to an electrical utility). The external electrical element 608 can be connected to a single rack system, such as via the second connection 644, and/or to multiple rack systems, such as via the third connection 646 which is an extension of the first connection 642. In some examples, when the rack systems 600 are connected in parallel, the third connection 646 is used such that each rack is connected to the external electrical element 608. In some examples, when the rack systems 600 are connected in series, only the first and second connections 642, 644 are used so that only a last rack system in the series of rack systems is connected to the external electrical element. The first, second, and third connections 642, 644, 646, though, can carry power (e.g., voltage and current) and in some examples, can additionally carry data between the rack systems 600 and external electrical element(s) 608. While the rack systems 600 of FIG. 6 are illustrated with modules and connections similar to or the same as the connections described in FIG. 1-4, the modules and connections therebetween in the rack systems 600 are not limited to such embodiments. For example, the modules and connections between modules in the rack systems 600 can include the jumper connections illustrated and described in FIG. 5.

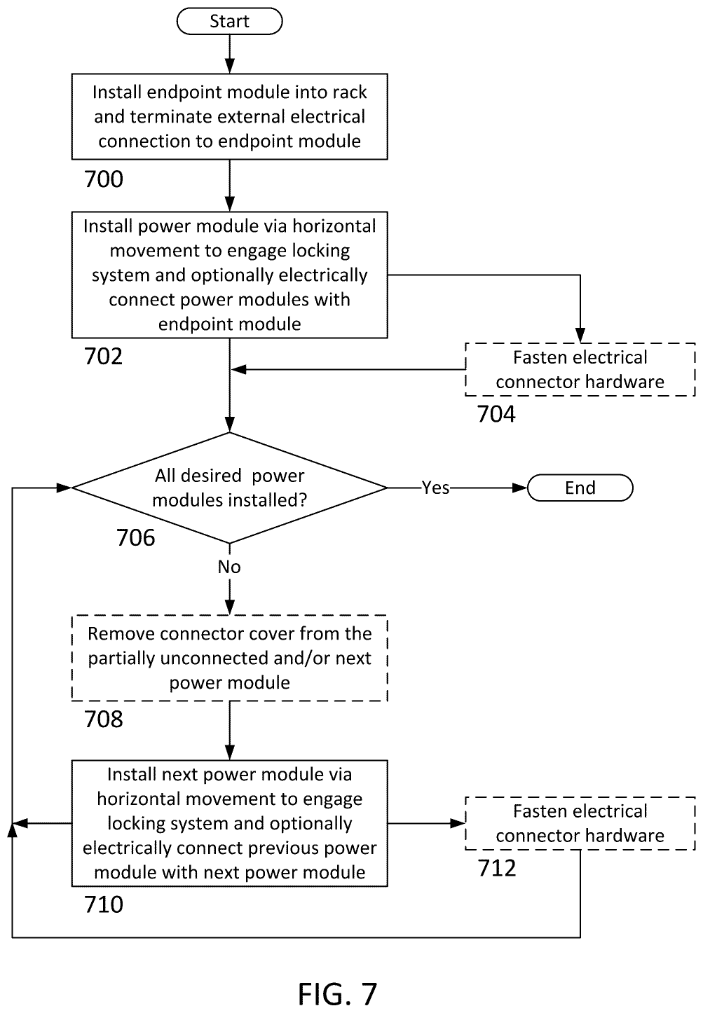

Moving to FIG. 7, FIG. 7 is a flow diagram of an example method of installing modules into a rack system according to an aspect of the present disclosure. Starting at 700, an endpoint module is installed into a rack system and an external electrical connection is terminated to the endpoint module. Terminating an electrical connection to the endpoint module can include electrically connecting the endpoint module to an external connection. In some examples, the endpoint module is electrically connected to more than one external connection.

Continuing with 702, the method includes installing a power module into the rack system. Specifically, the method includes installing the power module via horizontal movement relative to the endpoint module and engaging a locking system. The locking system can comprise different methods of locking. For example, as is described with respect to FIG. 3, a locking system can prevent a power module from being easily disconnected from another module (e.g., the endpoint module). Additionally or alternatively, a locking system can prevent a power module from being disconnected from the rack into which it is installed. The method optionally includes electrically connecting the power module with the endpoint module. This portion of step 702 can be part of the engagement between the power module and the endpoint module (e.g., as described with respect to FIG. 3).

After 702, the power module is engaged with the endpoint module and in some examples, is also in electrical connection with the endpoint module. However, in some examples, the method continues with 704, whereby electrical connector hardware is fastened between the power module and the endpoint module. In some examples, the electrical connector hardware comprises a jumper (e.g., 550) which is connected before another module is installed. In some examples, the fastening of electrical connector hardware in 704 occurs at a later portion of the method of FIG. 7 (e.g., step 712). For example, jumpers can be connected to modules after all modules have been installed.

At 706, the method can either end if all the desired power modules have been installed or continue with 708 or 710 if not all the desired power modules have been installed. If more power modules are desired, and the modules include a connector cover for transit purposes, the connector cover is removed from the next power module to be installed. Similarly, if more power modules are desired in a rack system after the rack system has already been operated with fewer power modules, a connector cover of the partially unconnected (e.g., top) power module is removed. This can enable another power module to connect to the unconnected portion of the power module. For example, adding another power module on top of the upper power processing module 402a of FIG. 4 can require the connector cover 410 to be removed first.

Continuing with 710, the method includes installing the next power module into the rack system. Specifically, the method includes installing the power module via horizontal movement relative to the previous power module and engaging a locking system. The locking system can include one or both of the locking system described in step 702. Step 710 of the method can optionally include electrically connecting the next power module with the previous power module. The optional portion of step 710 can be part of the engagement between the next power module and the previous power module (e.g., as described with respect to FIG. 4).

After 710, the next power module is engaged with the previous power module and in some examples, is also in electrical connection with the previous power module. In some examples, the method continues with 712, whereby electrical connector hardware is fastened between the next power module and the previous power module. As with step 704, the electrical connection hardware can comprise a jumper. In some examples, if the electrical connector hardware was not connected between the previous power module and the endpoint module, or was not connected between a previous power module and a next power module, electrical connector hardware is fastened between modules that are to be connected with each other.

After 712, the method can loop through the steps 708-712 until all desired power modules are installed. Once the desired number of power modules are installed (e.g., one or more), the method can end.

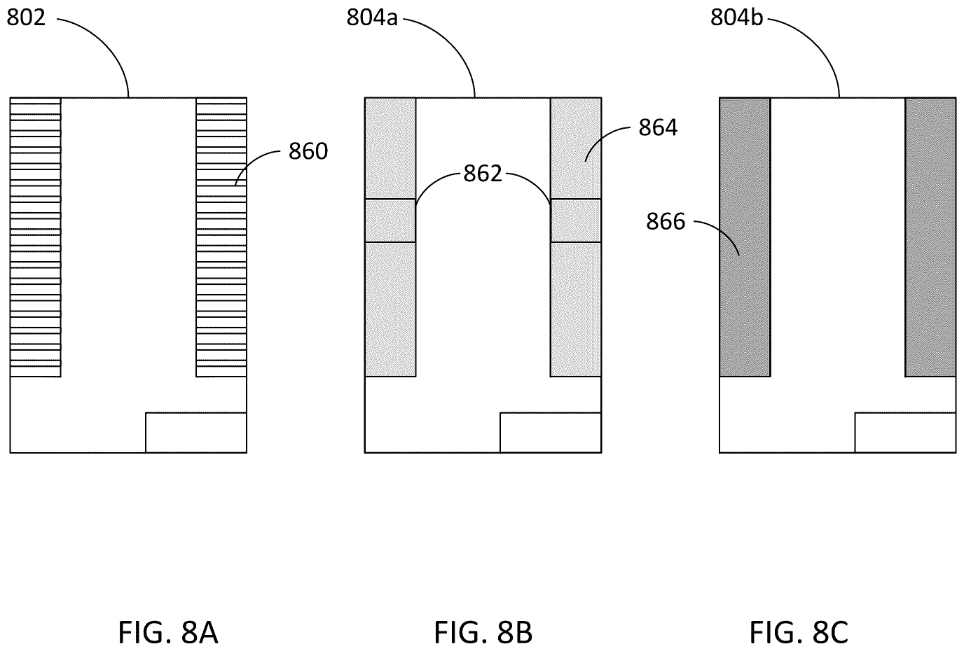

Moving to FIG. 8A-8C, FIG. 8A-C are schematic top views of example modules with various cooling mechanisms. The modules can be used in the rack systems described herein. Starting with FIG. 8A, FIG. 8A is a schematic top view of an example power processing module 802 with passive cooling elements 860 according to an aspect of the present disclosure. The cooling elements 860 are passive heat sinks that include fins for dissipating heat away from power processing circuitry (e.g., circuitry for DC/DC converters). The cooling elements 860 can extend along an entire height (e.g., into/out of the page) of the power processing module 802. In some examples, in addition to or in lieu of passive cooling, the power processing module 802 can include active cooling (e.g., fans).

FIG. 8B is a schematic top view of an example endpoint module 804a with active cooling elements according to an aspect of the present disclosure. The active cooling provided by the endpoint module 804a can include fans 862 located in ducts 864 that can move air through the ducts 864. Further, in some examples, the active cooling provided by the endpoint module 804a can be used in conjunction with the passive cooling of the power processing module 802. For example, the ducts 864 of the endpoint module 804a can match with the extend of the cooling elements 860 of the power processing module such that air blown by the fans flows through the ducts and around the cooling elements 860. Air that is moved over the cooling elements 860 can increase cooling performance of the cooling elements 860. In some examples, multiple power processing modules having the passive cooling elements 860 can be vertically stacked such that the fans 862 of the endpoint module 804a can blow air vertically along the stack and over all cooling elements of the power processing modules.

In an alternative to FIG. 8B, FIG. 8C is a schematic top view of an alternate example power processing module 804b with passive cooling elements 866 according to an aspect of the present disclosure. In some examples, the passive cooling elements 866 are similar to the cooling elements 860 of the power processing module 802. In some examples, the passive cooling elements 866 of the endpoint module are part of the cooling elements 860 of the power processing module 802. For example, the cooling elements 860 of the power processing module 802 can comprise a heat sink with fins while the passive cooling elements 866 of the endpoint module 804 comprise an extension of the heat sink. Passive cooling can be advantageous in instances where a rack system including an endpoint module and power processing modules is enclosed within a water-resistant enclosure.

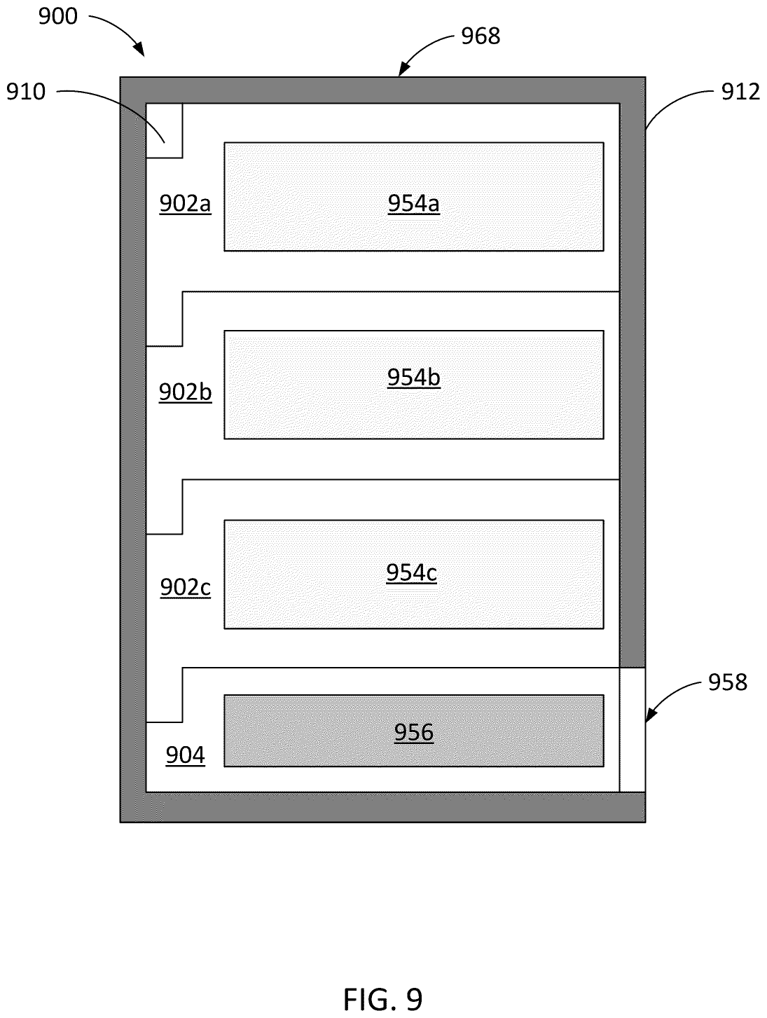

FIG. 9 is a schematic side view of an example rack system 900 including power processing modules 902a-c, an endpoint module 904, and a cooling system according to an aspect of the present disclosure. The cooling system includes active cooling elements 956 in the endpoint module 904 which is located at a bottom of the rack system 900. The active cooling elements 956 can include fans that take in air from an air intake 958 and ducts that direct air blown by the fans upward. The air intake can be located on one or more sides of the rack system 900. The ducts can lead directly to the passive heat sinks 954a-c of the power processing modules 902a-c, which are located above the endpoint module 904. In operation, the fans of the endpoint module can intake air and blow the air upward through the ducts and through each of the heat sinks 954a-c of the power processing modules 902a-c. The air can then exhaust out a top 986 of the rack system 900. Because the air passes over the heatsinks 954a-c, the heat sinks 954a-c can dissipate more heat than they otherwise could. Further, intaking cooler air from the bottom of the rack system 900 and exhausting air heated by the power processing modules 902a-c out the top can aid in the natural convective cooling of the rack system 900.

Various examples have been described. These and other examples are within the scope of this disclosure.

1. A modular power processing system comprising:
a first power processing module configured to be supported by a rack structure, the first power processing module comprising:
first power conversion circuitry configured to convert power between AC/DC power and/or between DC/DC power; and
a first top connector;
a second power processing module configured to be supported by the rack structure, the second power processing module comprising:
second power conversion circuitry configured to convert power between AC/DC power and/or between DC/DC power; and
a second bottom connector; wherein
the first top connector of the first power processing module is configured to self-align and engage with the second bottom connector of the second power processing module, the engagement of the first top connector with the second bottom connector establishing electrical communication between the first power processing module and the second power processing module.

2. The modular power processing system of claim 1, wherein:
the first power processing module further comprises a first bottom connector, the first bottom connector configured to align and engage with a third top connector of a third power processing module, the engagement of the first bottom connector and the third top connector establishing electrical communication between the first power processing module and the third power processing module.

3. The modular power processing system of claim 1, wherein:
the second power processing module further comprises a second top connector, the second top connector configured to align and engage with a third bottom connector of a third power processing module, the engagement of the second top connector and the third bottom connector establishing electrical communication between the second power processing module and the third power processing module.

4. The modular power processing system of claim 1, wherein at least one of the first top connector and the second bottom connector comprises a locking mechanism, the locking mechanism preventing disconnection between the second bottom connector and the first top connector.

5. The modular power processing system of claim 1, further comprising a connector cover, the connector cover configured to secure to and cover a second top connector of the second power processing module.

6. The modular power processing system of claim 1, further comprising an endpoint module configured to electrically connect to the first power processing module, the endpoint module including an electrical interface for external electrical connections to the modular power processing system.

7. The modular power processing system of claim 6, wherein:
the endpoint module comprises one or more active cooling elements; and
the first power processing module and the second power processing module each include passive cooling elements configured to dissipate heat from their respective power conversion circuitry.

8. The modular power processing system of claim 6, wherein the electrical connection between the endpoint module and the first power processing module carries both power and data.

9. The modular power processing system of claim 1, wherein the first and second power processing modules are configured to be added to or removed from the rack structure without the use of tools.

10. The modular power processing system of claim 1, wherein the electrical communication between the first power processing module and the second power processing module includes transmitting both power and data.

11. The modular power processing system of claim 1, wherein the system is IP 67 rated and rated for outdoor use.

12. The modular power processing system of claim 1, wherein the first power processing module and the second power processing module are each rated for between 100 kW and 200 kW of power.

13. A method of installing modules into a modular power processing rack system, comprising:
installing an endpoint module into a rack structure;
installing a first power processing module into the rack structure by moving the first power processing module horizontally relative to the endpoint module, the relative movement causing the first power processing module to align a first bottom connector with a corresponding top connector of the endpoint module, engagement of the first bottom connector with the corresponding top connector, and establishment of electrical communication between the first power processing module and the endpoint module; and
installing a second power processing module into the rack structure by moving the second power processing module horizontally relative to the first power processing module, the horizontal movement causing the second power processing module to self-align a second bottom connector with a first top connector of the first power processing module, engagement of the second bottom connector with the first top connector, and establishment of electrical communication between the second power processing module and the first power processing module.

14. The method of claim 13, further comprising installing one or more additional power processing modules, the installation comprising:
moving the additional power processing module horizontally relative to a previously installed power processing module, the horizontal movement causing the additional power processing module to align a bottom connector of the additional power processing module with a top connector of the previously installed power processing module, engagement of the bottom connector with the top connector, and establishment of electrical communication between the additional power processing module and the previously installed power processing module.

15. The method of claim 13, further comprising:
prior to installing the second power processing module, removing a connector cover from the first top connector of the first power processing module.

16. The method of claim 13, wherein installing the second power processing module further comprises:
engaging a locking mechanism, the locking mechanism preventing disconnection of the bottom connector of the second power processing module from the top connector of the first power processing module.

17. The method of claim 13, further comprising:
installing a connector cover to a second top connector of the second power processing module, the connector cover covering one or more electrical contacts of the second top connector.

18. The method of claim 13, wherein the electrical communication established during the installing steps enables transmission of both power and data signals between electrically connected modules.

19. The method of claim 13, wherein each installing step is performed without the use of tools.

20. The modular power processing system of claim 13, wherein the first power processing module and the second power processing module are each rated for between 100 kW and 200 kW of power.
